(19) United States
(12) Patent Application Publication
(10) Pub. No.: US 2008/0121917 A1
(43) Pub. Date: May 29, 2008

(54) HIGH EFFICIENCY WHITE, SINGLE OR MULTI-COLOR LIGHT EMITTING DIODES (LEDS) BY INDEX MATCHING STRUCTURES

(75) Inventors: Claude C. A. Weisbuch, Paris (FR); James S. Speck, Goleta, CA (US); Steven P. DenBaars, Goleta, CA (US)

Correspondence Address: GATES & COOPER LLP;HOWARD HUGHES CENTER, 6701 CENTER DRIVE WEST, SUITE 1050, LOS ANGELES, CA, 90045, US

(73) Assignee: THE REGENTS OF THE UNIVERSITY OF CALIFORNIA, Oakland, CA (US)

(21) Appl. No.: 11/940,853

(22) Filed: Nov. 15, 2007

Related U.S. Application Data
(60) Provisional application No. 60/866,026, filed on Nov. 15, 2006.

(51) Int. Cl. H01L 33/00

(52) U.S. Cl. 257/98; 438/29; 257/E33.067

(57) ABSTRACT

Light emitting diode (LED) structures with an overstructure material having a refractive-index matched to the active layer and ways to produce such materials are disclosed. Various implementations of such structures to provide very high extraction efficiency and color control such as white light emission are also disclosed.

### CROSS-REFERENCE TO RELATED APPLICATIONS

This application claims the benefit under 35 U.S.C. Section 119(e) of the following co-pending and commonly-assigned U.S. patent applications:

U.S. Provisional Application Ser. No. 60/866,026, filed on Nov. 15, 2006, by Claude C. A. Weisbuch, James S. Speck and Steven P. Denbaars, titled “HIGH EFFICIENCY WHITE, SINGLE OR MULTI-COLOR LIGHT EMITTING DIODES (LEDS) BY INDEX MATCHING STRUCTURES,” attorneys' docket number 30794.196-US-P1 (2007-114-1);

which application is incorporated by reference herein.

This application is related to the following co-pending and commonly-assigned applications:

U.S. Utility application Ser. No. 10/581,940, filed on Jun. 7, 2006, by Tetsuo Fujii, Yan Gao, Evelyn. L. Hu, and Shuji Nakamura, entitled “HIGHLY EFFICIENT GALLIUM NITRIDE BASED LIGHT EMITTING DIODES VIA SURFACE ROUGHENING,” attorney's docket number 30794.108-US-WO (2004-063), which application claims the benefit under 35 U.S.C Section 365(c) of PCT Application Serial No. US2003/03921, filed on Dec. 9, 2003, by Tetsuo Fujii, Yan Gao, Evelyn L. Hu, and Shuji Nakamura, entitled “HIGHLY EFFICIENT GALLIUM NITRIDE BASED LIGHT EMITTING DIODES VIA SURFACE ROUGHENING,” attorney's docket number 30794.108-WO-01 (2004-063);

U.S. Utility application Ser. No. 11/054,271, filed on Feb. 9, 2005, by Rajat Sharma, P. Morgan Pattison, John F. Kaeding, and Shuji Nakamura, entitled “SEMICONDUCTOR LIGHT EMITTING DEVICE,” attorney's docket number 30794.112-US-01 (2004-208);

U.S. Utility application Ser. No. 10/938,704, filed on Sep. 10, 2004, by Carole Schwach, Claude C. A. Weisbuch, Steven P. DenBaars, Henri Benisty and Shuji Nakamura, entitled “WHITE, SINGLE OR MULTICOLOR LED BY RECYCLING GUIDED MODES,” attorney's docket number 30794.115-US-01 (2004-064);

U.S. Utility application Ser. No. 11/175,761, filed on Jul. 6, 2005, by Akihiko Murai, Lee McCarthy, Umesh K. Mishra and Steven P. DenBaars, entitled “METHOD FOR WAFER BONDING (Al, In, Ga)N and Zn(S, Se) FOR OPTOELECTRONICS APPLICATIONS,” attorney's docket number 30794.116-US-U1 (2004-455), which application claims the benefit under 35 U.S.C Section 119(e) of U.S. Provisional Application Ser. No. 60/585,673, filed Jul. 6, 2004, by Akihiko Murai, Lee McCarthy, Umesh K. Mishra and Steven P. DenBaars, entitled “METHOD FOR WAFER BONDING (Al, In, Ga)N and Zn(S, Se) FOR OPTOELECTRONICS APPLICATIONS,” attorney's docket number 30794.116-US-P1 (2004-455-1);

U.S. Utility application Ser. No. 11/067,957, filed Feb. 28, 2005, by Claude C. A. Weisbuch, Aurelien J. F. David, James S. Speck and Steven P. DenBaars, entitled “HORIZONTAL EMITTING, VERITCAL EMITTING, BEAM SHAPED, DISTRIBUTED FEEDBACK (DFB) LASERS BY GROWTH OVER A PATTERNED SUBSTRATE,” attorneys' docket number 30794.121-US-01 (2005-144-1);

U.S. Utility application Ser. No. 11/067,910, filed Feb. 28, 2005, by Claude C. A. Weisbuch, Aurelien J. F. David, James S. Speck and Steven P. DenBaars, entitled “SINGLE OR MULTI-COLOR HIGH EFFICIENCY LIGHT EMITTING DIODE (LED) BY GROWTH OVER A PATTERNED SUBSTRATE,” attorneys' docket number 30794.122-US-01 (2005-145-01);

U.S. Utility application Ser. No. 11/067,956, filed Feb. 28, 2005, by Aurelien J. F. David, Claude C. A Weisbuch and Steven P. DenBaars, entitled “HIGH EFFICIENCY LIGHT EMITTING DIODE (LED) WITH OPTIMIZED PHOTONIC CRYSTAL EXTRACTOR,” attorneys' docket number 30794.126-US-01 (2005-198-1);

U.S. Utility application Ser. No. 11/403,624, filed Apr. 13, 2006, by James S. Speck, Troy J. Baker and Benjamin A. Haskell, entitled “WAFER SEPARATION TECHNIQUE FOR THE FABRICATION OF FREE-STANDING (AL, IN, GA)N WAFERS,” attorneys' docket number 30794.131-US-U1 (2005-482-2), which application claims the benefit under 35 U.S. C Section 119(e) of U.S. Provisional Application Ser. No. 60/670,810, filed Apr. 13, 2005, by James S. Speck, Troy J. Baker and Benjamin A. Haskell, entitled “WAFER SEPARATION TECHNIQUE FOR THE FABRICATION OF FREE-STANDING (AL, IN, GA)N WAFERS,” attorneys' docket number 30794.131-US-P1 (2005-482-1);

U.S. Utility application Ser. No. 11/403,288, filed Apr. 13, 2006, by James S. Speck, Benjamin A. Haskell, P. Morgan Pattison and Troy J. Baker, entitled “ETCHING TECHNIQUE FOR THE FABRICATION OF THIN (AL, IN, GA)N LAYERS,” attorneys' docket number 30794.132-US-U1 (2005-509-2), which application claims the benefit under 35U.S.C Section 119(e) of U.S. Provisional Application Ser. No. 60/670,790, filed Apr. 13, 2005, by James S. Speck, Benjamin A. Haskell, P. Morgan Pattison and Troy J. Baker, entitled “ETCHING TECHNIQUE FOR THE FABRICATION OF THIN (AL, IN, GA)N LAYERS,” attorneys' docket number 30794.132-US-P1 (2005-509-1);

U.S. Utility application Ser. No. 11/454,691, filed on Jun. 16, 2006, by Akihiko Murai, Christina Ye Chen, Daniel B. Thompson, Lee S. McCarthy, Steven P. DenBaars, Shuji Nakamura, and Umesh K. Mishra, entitled “(Al, Ga, In)N AND ZnO DIRECT WAFER BONDING STRUCTURE FOR OPTOELECTRONIC APPLICATIONS AND ITS FABRICATION METHOD,” attorneys' docket number 30794.134-US-U1 (2005-536-4), which application claims the benefit under 35 U.S.C Section 119(e) of U.S. Provisional Application Ser. No. 60/691,710, filed on Jun. 17, 2005, by Akihiko Murai, Christina Ye Chen, Lee S. McCarthy, Steven P. DenBaars, Shuji Nakamura, and Umesh K. Mishra, entitled “(Al, Ga, In)N AND ZnO DIRECT WAFER BONDING STRUCTURE FOR OPTOELECTRONIC APPLICATIONS, AND ITS FABRICATION METHOD,” attorneys' docket number 30794.134-US-P1 (2005-536-1), U.S. Provisional Application Ser. No. 60/732,319, filed on Nov. 1, 2005, by Akihiko Murai, Christina Ye Chen, Daniel B. Thompson, Lee S. McCarthy, Steven P. DenBaars, Shuji Nakamura, and Umesh K. Mishra, entitled “(Al, Ga, In)N AND ZnO DIRECT WAFER BONDED STRUCTURE FOR OPTOELECTRONIC APPLICATIONS, AND ITS FABRICATION METHOD,” attorneys' docket number 30794.134-US-P2 (2005-536-2), and U.S. Provisional Application Ser. No. 60/764,881, filed on Feb. 3, 2006, by Akihiko Murai, Christina Ye Chen, Daniel B. Thompson, Lee S. McCarthy, Steven P. DenBaars, Shuji Nakamura, and Umesh K. Mishra, entitled “(Al, Ga, In)N AND ZnO DIRECT WAFER BONDED STRUCTURE FOR OPTOELECTRONIC APPLICATIONS AND ITS FABRICATION METHOD,” attorneys' docket number 30794.134-US-P3 (2005-536-3);

U.S. Utility application Ser. No. 11/251,365 filed Oct. 14, 2005, by Frederic S. Diana, Aurelien J. F. David, Pierre M. Petroff, and Claude C. A. Weisbuch, entitled “PHOTONIC STRUCTURES FOR EFFICIENT LIGHT EXTRACTION AND CONVERSION IN MULTI-COLOR LIGHT EMITTING DEVICES,” attorneys' docket number 30794.142-US-01 (2005-534-1);

U.S. Utility application Ser. No. 11/633,148, filed Dec. 4, 2006, Claude C. A. Weisbuch and Shuji Nakamura, entitled “IMPROVED HORIZONTAL EMITTING, VERTICAL EMITTING, BEAM SHAPED, DISTRIBUTED FEEDBACK (DFB) LASERS FABRICATED BY GROWTH OVER A PATTERNED SUBSTRATE WITH MULTIPLE OVERGROWTH,” attorneys' docket number 30794.143-US-U1 (2005-721-2), which application claims the benefit under 35 U.S.C Section 119(e) of U.S. Provisional Application Ser. No. 60/741,935, filed Dec. 2, 2005, Claude C. A. Weisbuch and Shuji Nakamura, entitled “IMPROVED HORIZONTAL EMITTING, VERTICAL EMITTING, BEAM SHAPED, DFB LASERS FABRICATED BY GROWTH OVER PATTERNED SUBSTRATE WITH MULTIPLE OVERGROWTH,” attorneys' docket number 30794.143-US-P1 (2005-721-1);

U.S. Utility application Ser. No. 11/593,268, filed on Nov. 6, 2006, by Steven P. DenBaars, Shuji Nakamura, Hisashi Masui, Natalie N. Fellows, and Akihiko Murai, entitled “HIGH LIGHT EXTRACTION EFFICIENCY LIGHT EMITTING DIODE (LED),” attorneys' docket number 30794.161-US-U1 (2006-271-2), which application claims the benefit under 35 U.S.C Section 119(e) of U.S. Provisional Application Ser. No. 60/734,040, filed on Nov. 4, 2005, by Steven P. DenBaars, Shuji Nakamura, Hisashi Masui, Natalie N. Fellows, and Akihiko Murai, entitled “HIGH LIGHT EXTRACTION EFFICIENCY LIGHT EMITTING DIODE (LED),” attorneys' docket number 30794.161-US-P1 (2006-271-1);

U.S. Utility application Ser. No. 11/608,439, filed on Dec. 8, 2006, by Steven P. DenBaars, Shuji Nakamura and James S. Speck, entitled “HIGH EFFICIENCY LIGHT EMITTING DIODE (LED),” attorneys' docket number 30794.164-US-U1 (2006-318-3), which application claims the benefit under 35 U.S.C Section 119(e) of U.S. Provisional Application Ser. No. 60/748,480, filed on Dec. 8, 2005, by Steven P. DenBaars, Shuji Nakamura and James S. Speck, entitled “HIGH EFFICIENCY LIGHT EMITTING DIODE (LED),” attorneys' docket number 30794.164-US-P1 (2006-318-1), and U.S. Provisional Application Ser. No. 60/764,975, filed on Feb. 3, 2006, by Steven P. DenBaars, Shuji Nakamura and James S. Speck, entitled “HIGH EFFICIENCY LIGHT EMITTING DIODE (LED),” attorneys' docket number 30794.164-US-P2 (2006-318-2);

U.S. Utility application Ser. No. 11/676,999, filed on Feb. 20, 2007, by Hong Zhong, John F. Kaeding, Rajat Sharma, James S. Speck, Steven P. DenBaars and Shuji Nakamura, entitled “METHOD FOR GROWTH OF SEMIPOLAR (Al, In, Ga, B)N OPTOELECTRONIC DEVICES,” attorneys' docket number 30794.173-US-U1 (2006-422-2), which application claims the benefit under 35 U.S.C Section 119(e) of U.S. Provisional Application Ser. No. 60/774,467, filed on Feb. 17, 2006, by Hong Zhong, John F. Kaeding, Rajat Sharma, James S. Speck, Steven P. DenBaars and Shuji Nakamura, entitled “METHOD FOR GROWTH OF SEMIPOLAR (Al, In, Ga, B)N OPTOELECTRONIC DEVICES,” attorneys' docket number 30794.173-US-P1 (2006-422-1);

U.S. Utility patent application Ser. No. ______, filed on same date herewith, by Aurelien J. F. David, Claude C. A. Weisbuch and Steven P. DenBaars entitled “HIGH LIGHT EXTRACTION EFFICIENCY LIGHT EMITTING DIODE (LED) THROUGH MULTIPLE EXTRACTORS,” attorney's docket number 30794. 191-US-U1 (2007-047-3), which application claims the benefit under 35 U.S.C Section 119(e) of U.S. Provisional Patent Application Ser. No. 60/866,014, filed on Nov. 15, 2006, by Aurelien J. F. David, Claude C. A. Weisbuch and Steven P. DenBaars entitled “HIGH LIGHT EXTRACTION EFFICIENCY LIGHT EMITTING DIODE (LED) THROUGH MULTIPLE EXTRACTORS,” attorney's docket number 30794. 191-US-P1 (2007-047-1), and U.S. Provisional Patent Application Ser. No. 60/883,977, filed on Jan. 8, 2007, by Aurelien J. F. David, Claude C. A. Weisbuch and Steven P. DenBaars entitled “HIGH LIGHT EXTRACTION EFFICIENCY LIGHT EMITTING DIODE (LED) THROUGH MULTIPLE EXTRACTORS,” attorney's docket number 30794. 191-US-P2 (2007-047-2); and

U.S. Utility patent application Ser. No. ______, filed on same date herewith, by Aurelien J. F. David, Claude C. A. Weisbuch, Steven P. DenBaars and Stacia Keller, entitled “HIGH LIGHT EXTRACTION EFFICIENCY LIGHT EMITTING DIODE (LED) WITH EMITTERS WITHIN STRUCTURED MATERIALS,” attorney's docket number 30794. 197-US-U1 (2007-113-2), which application claims the benefit under 35 U.S.C Section 119(e) of U.S. Provisional Patent Application Ser. No. 60/866,015, filed on Nov. 15, 2006, by Aurelien J. F. David, Claude C. A. Weisbuch, Steven P. DenBaars and Stacia Keller, entitled “HIGH LIGHT EXTRACTION EFFICIENCY LIGHT EMITTING DIODE (LED) WITH EMITTERS WITHIN STRUCTURED MATERIALS,” attorney's docket number 30794. 197-US-P1 (2007-113-1);

which applications are incorporated by reference herein.

### BACKGROUND OF THE INVENTION

1. Field of the Invention

This invention relates to light emitting diodes (LEDs) and more particularly to new structures for producing LEDs with high extraction efficiency.

2. Description of the Related Art

(Note: This application references a number of different publications and patents as indicated throughout the specification by one or more reference numbers within brackets, e.g., [x]. A list of these different publications and patents ordered according to these reference numbers can be found below in the section entitled “References.” Each of these publications and patents is incorporated by reference herein.)

A light emitting diode (LED) is a semiconductor device that emits light when electrically biased in the forward direction. This effect is a form of electroluminescence.

Improvements in semiconductor materials have led to improved semiconductor device efficiency and have enabled devices emitting new wavelength ranges. Gallium nitride (GaN) based light emitters are probably the most promising for a variety of applications, although other III-nitride materials may also be used. GaN provides efficient illumination in the ultra-violet ultraviolet (UV) to amber spectrum when alloyed with varying concentrations of, for example, indium.

Unfortunately, most of the light emitted within a semiconductor LED material is lost due to total internal reflection at the semiconductor-air interface. Typical semiconductor materials have a high index of refraction and therefore, according to Snell's law, most of the light remains trapped in the materials resulting in degraded efficiency.

By choosing a suitable geometry for the LED, a higher extraction efficiency is achievable. However, this is only possible in some rare instances by shaping the emitting material itself Then, extraction efficiency can be quite high [11,12].

A more general way to improve light extraction is to place, on the active material, a shaped material having an index of refraction higher than the index of refraction for air. In that case, the critical angle increases and, due to the shaping of the material (for example, into a dome or pyramid), the light extracted in the material will be further extracted into air.

However, as long as the top material has an index of refraction smaller than the index of refraction for the emitting layer, a sizeable fraction of light remains trapped in the emitting material because of total internal reflection. For instance, for an emitting material having an index of refraction n=2.4, the fraction of light trapped is 91% if the outside medium is air (n=1), 78% if the outside medium is epoxy (n=1.5), 48% if the outside medium is zinc oxide (ZnO) (n=2.1) and it is still 29% if an outside medium having an index n=2.3 is used.

Another method of destroying the effects of the total internal reflection is to create light scattering in the form of random texturing on the surface, which leads to multiple variable-angle incidence at the semiconductor-air interface. This approach has been shown to improve emission efficiency by 9-30%, because of the very high internal efficiency and low internal losses which allows many passes for the light before the light escapes [13-18].

Another method to reduce the percentage of light trapped is to use a Micro-Cavity LED (MCLED) or Resonant Cavity LED (RCLED). MCLEDs offer opportunities to create solid-state lighting systems with greater efficiencies than existing systems using ‘traditional’ LEDs. As a result of incorporating a gain medium within a resonant cavity, MCLEDs emit a highly compact and directional light beam. The higher extraction efficiency and high brightness of these devices are the main advantages of these technologies over conventional LEDs. Extraction efficiency refers to the ability of the photons generated by a particular system to actually exit the system as ‘useful’ radiation [19,20]

Other solutions rely on the use of surfaces structured at the wavelength scale able to diffract the waveguided light, such as photonic crystals [21].

All these solutions are, however, quite demanding in terms of fabrication. This is why a solution relying on suppressing the trapped light, acting on the primary cause for light trapping, is more preferable.

The present invention suppresses trapped light by using, as an escape facilitator, a material with an index of refraction matching that of the emitting layer (for example, n=2.4 in a GaN-based LED). Then, by shaping or structuring the inside or the surface of this material, light contained in the extracted structure may be extracted.

### SUMMARY OF THE INVENTION

The present invention describes new LED structures that provide enhanced light extraction efficiency in single color, multi-color or white light LEDs and retain a planar structure. The new LED structures have little or no guided light because of an overstructure that an index of refraction at least matching an index of refraction of the emitting active layer. The new LEDs may also be high-efficiency white, single or multi-color LEDs because of re-emission by additional light emitting species, such as dyes or quantum dots (QDs), incorporated in the LED.

The index matching of the overstructure enables suppression of the difficult to extract guided light which is usually found in LEDs. The extraction of light in the overall structure is provided by the inhomogeneity of the overstructure, wherein the inhomogeneity is achieved, for example, by shaping the overstructure, by incorporating variable index particles or holes in the overstructure, by structuring the overstructure surface, or by a combination of such means.

The structure usually comprises a bottom metallic mirror, a substrate, a buffer layer, an active layer containing single or multiple current-injected quantum wells, and a geometrical structure (such as a layer, dome, pyramid or roughened layer) on the top, which has an index of refraction matching the index of refraction of the active layer material. The addition of secondary emitters in the geometrical structure provides emitters having color rendering properties. These electrically-passive emitters used for color rendering can be as diverse as phosphors, dye molecules, small light emitting molecules, light emitting polymers, or quantum dots.

### BRIEF DESCRIPTION OF THE DRAWINGS

Referring now to the drawings in which like reference numbers represent corresponding parts throughout:

FIG. 1 is a schematic cross-section showing light emission processes in an (Al, Ga, In)N structure.

FIG. 2 is a schematic illustrating light extraction in an (Al, Ga, In)N structure with a dome-shaped epoxy overstructure.

FIG. 3 is a schematic illustrating an (Al, Ga, In)N structure with a ZnO pyramid extractor overstructure.

FIG. 4 is a schematic illustrating an (Al, Ga, In)N structure with a bottom mirror and a dome-shaped overstructure made with index matched material.

FIG. 5 is a schematic illustrating an (Al, Ga, In)N structure with a bottom mirror and a pyramid-shaped overstructure made with index matched material.

FIG. 6 is a schematic illustrating an (Al, Ga, In)N structure with a bottom mirror, an overstructure made with index matched material, where the overstructure material has inclusions, and wherein the inclusion refractive index is different from the matrix refractive index.

FIG. 7 is a schematic illustrating an (Al, Ga, In)N structure with a bottom mirror, an overstructure made with an index matched material and where the overstructure has surface roughening or structuring.

FIG. 8 is a schematic of light extraction in an (Al, Ga, In)N structure with a bottom mirror and a dome-shaped overstructure made with index matched material, where the overstructure material contains light emitting species under photoexcitation.

FIG. 9 is a schematic of light extraction in an (Al, Ga, In)N structure with a bottom mirror, an overstructure made with index matched material and where transparent electrodes are being used.

FIG. 10 is a schematic of light extraction in an (Al, Ga, In)N structure with electrodes, an overstructure made with index matched material, and where the structure is surrounded by a high index material acting as a beam expander.

### DETAILED DESCRIPTION OF THE INVENTION

In the following description of the preferred embodiment, reference is made to the accompanying drawings which form a part hereof, and in which is shown by way of illustration a specific embodiment in which the invention may be practiced. It is to be understood that other embodiments may be utilized and structural changes may be made without departing from the scope of the present invention.

Technical Description

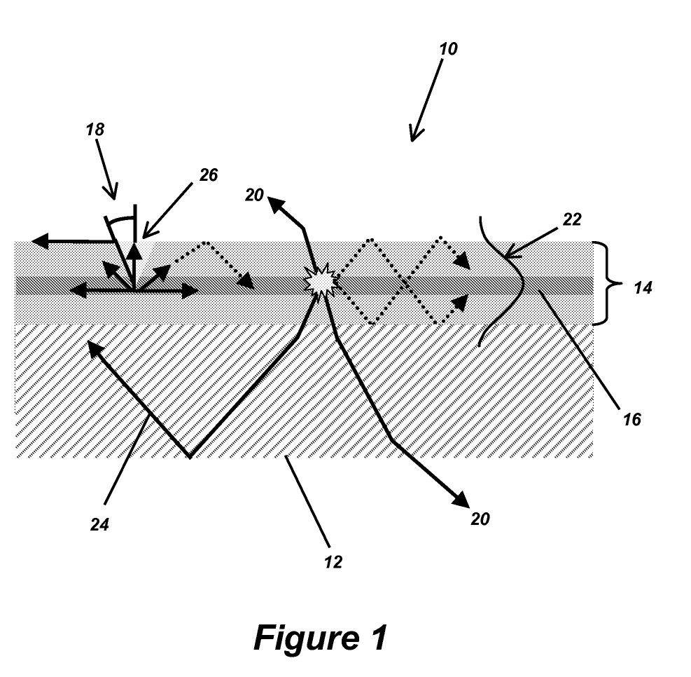

FIG. 1 shows the various paths for light emission in a common LED structure 10, which comprises a substrate 12 and (Al, In, Ga)N layer(s) 14, which includes a light-emitting active layer 16 having quantum wells (QWs).

Generally, the (Al, In, Ga)N layers 14 and active layer 16 are considered a single sequence of layers. In this regard, the sequence of the (Al, In, Ga)N layers 14 is an ensemble comprised of insulating and semiconducting materials formed on the substrate 12 and including one or more III-nitride active layers 16 for emitting light. For example, the ensemble may include an optional III-nitride buffer layer, doped III-nitride layers 14, III-nitride quantum well layers 16, III-nitride confining layers 14, and other layers usually found in an LED 10, according to the well-known designs of light emitting III-nitride based LEDs.

In the LED 10 of FIG. 1, some light will be emitted into directions within a critical angle 18 for external emission or extraction 20, the critical angle 18 being defined as the internal angle for which light emerges from the LED structure 10 at grazing incidence. However, most of the light undergoes total internal reflection at angles larger than the critical angle 18 for extraction, leading predominantly to waveguided modes 22 in the (Al, In, Ga)N layers 14 and active layer 16, but also to some other light 24 trapped in the substrate 12.

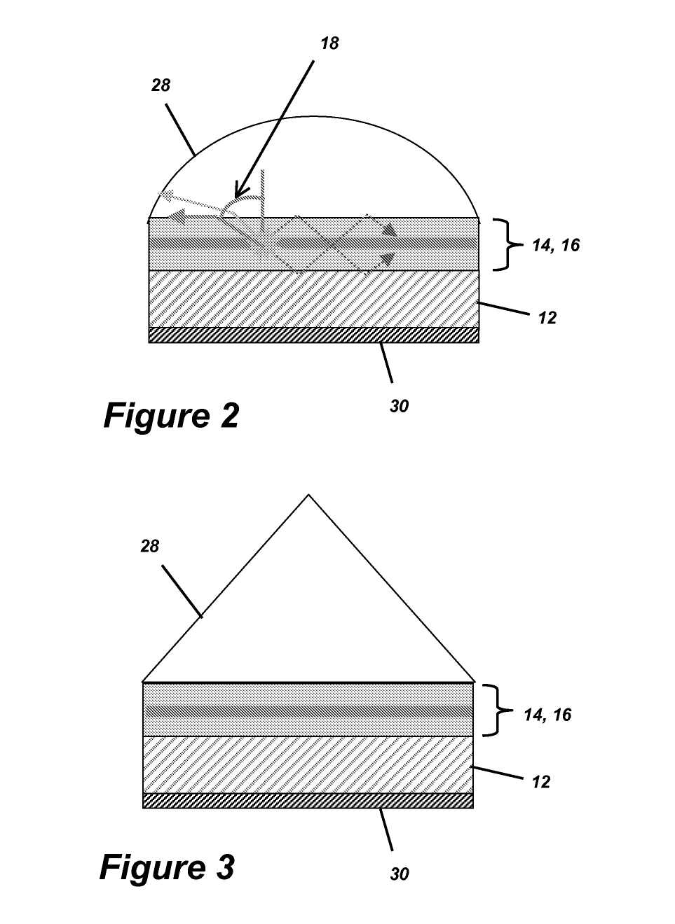

One method for improving this situation, by extracting 26 the light 24 trapped in the substrate 12, is to use an overstructure over the (Al, In, Ga)N layers 14 which, because the overstructure material has an index of refraction higher than that of air, leads to a larger critical angle than the critical angle for direct extraction into air. In order for all light beams contained in the overstructure to escape into air, the overstructure 28 may comprise epoxy shaped into domes, as illustrated in FIG. 2, or the overstructure 28 may comprise ZnO shaped into pyramids, as illustrated in FIG. 3, or the overstructure 28 may comprise some other material fabricated into some other shape.

In addition, a mirror 30 may be placed on a backside surface of the substrate 12 to assist in the extraction of reflected light. For example, the mirror 30 may be positioned in proximity to the ensemble for reflecting the emitted light within the device 10 towards the overstructure 28, so that the emitted light interacts with light extracting features of the overstructure 28.

The main idea of the present invention is to use the overstructure 28 formed over the ensemble, e.g., on top of the LED 10, for efficiently suppressing guided modes 22 within the ensemble by using a material for the overstructure 28 having an index of refraction at least matching an index of refraction of the (Al, In, Ga)N layers 14 and active layer 16, wherein the overstructure 28 acts as a light extractor for the emitted light.

Indeed, the refractive index of the material of the overstructure 28 may be higher than the refractive index of the (Al, In, Ga)N layers 14 and active layer 16. Moreover, the overstructure 28 may be comprised of various materials having high and low refractive indexes.

Having suppressed the guided modes 22 in the active layer 16, light from the composite structure comprising the (Al, In, Ga)N layers 14, the active layer 16 and the overstructure 28 must be extracted. This may be achieved in a number of ways.

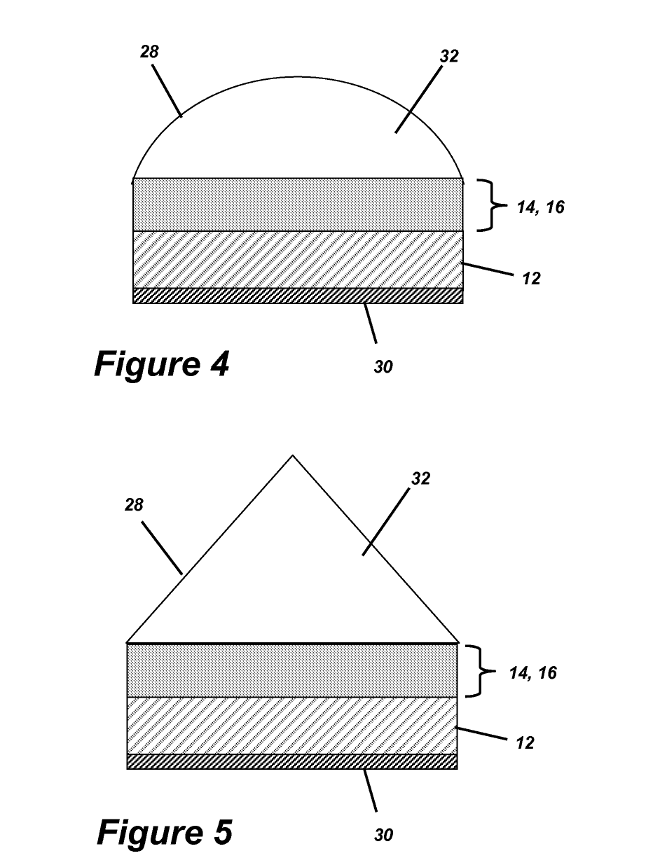

In one method, the overstructure 28 can be shaped such that it extracts light. Overstructure 28 shaped as domes or pyramids are commonly used, as represented in FIGS. 4 and 5, respectively, wherein the overstructure 28 in these figures is comprised of a material 32 that includes an index matching layer, i.e., a material 32 that at least matches the refractive index of the (Al, In, Ga)N layers 14 and active layer 16.

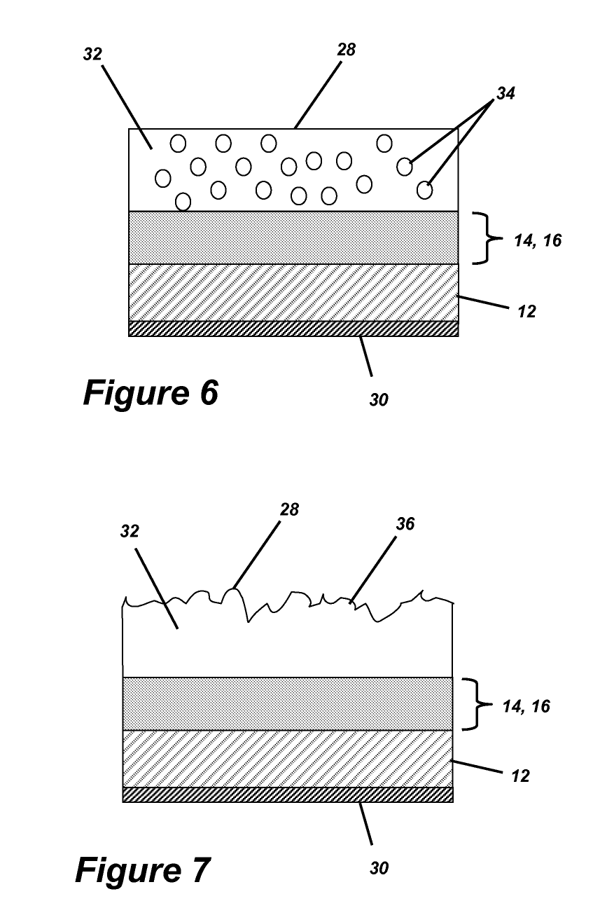

In addition, or alternatively, the overstructure 28 may be comprised of a material 32 with an index matching layer that includes inhomogeneities 34 for efficiently scattering the emitted light out of the overstructure 28, such as gas inclusions or materials with an index of refraction different from the refractive index of the matrix of materials comprising the overstructure 28, as shown in FIG. 6. These inhomogeneities 34 may be achieved by shaping the overstructure 28, by incorporating materials having a variable index of refraction into the overstructure 28, by incorporating holes into the overstructure 28, or by structuring a surface of the overstructure 28.

Currently, very few practical materials exist (e.g., in a form that can be practically used) that have an index matching that of layers 14, 16. Therefore, one of the ways to obtain a high enough index structure is to incorporate a higher index material into the main material 32 of the overstructure 28. The main materials 32 of the overstructure 28 are known as the matrix of the overstructure 28, which itself does not have a high enough index to match that of the layers 14, 16.

The higher index material is preferably transparent, such as gallium phosphide (GaP) or titanium dioxide (TiO₂), which exists in various shapes and in the desired particle size range of microns to nanometers. Alternative, an absorbing material such as silicon might be used if in limited concentrations and thicknesses.

Yet another efficient way to extract light from the overstructure 28 could be by disturbing the planarity of the surface of the overstructure 28, wherein a top surface 36 of the overstructure 28 is roughened, textured, patterned, or formed into a shape to enhance extraction of the emitted light, as illustrated in FIG. 7. In this case, the non-planar interface of the surface with air randomizes incoming beam directions, and after a few attempts to escape, a beam will be within the escape angle.

Any method can be used to fabricate and deposit the material 32 of the overstructure 28. The material 32 can be deposited and then molded or imprinted into a desired shape. Alternatively, the material 32 of the overstructure 28 can be spun-on using a spin-on technique or other similar techniques. A widely used technique relies on deposition of hybrid sol-gel solutions containing sol-gel materials and particles with high index of refraction. Other techniques such as physical deposition (MBE, MOCVD, evaporation, sputtering), chemical deposition (MOCVD, thermal growth) and other similar techniques can also be used.

The advantages of the present invention over texturing, patterning or roughening the surface of the (Al, In, Ga)N layer 14 itself are that: (1) it is not easy to texture, pattern or roughen the surface of the (Al, Ga, In)N layer 14, and (2) the process used in texturing, patterning or roughening the surface of the (Al, In, Ga)N layer 14 usually degrades the optoelectronic performance of the (Al, Ga, In)N layer 14.

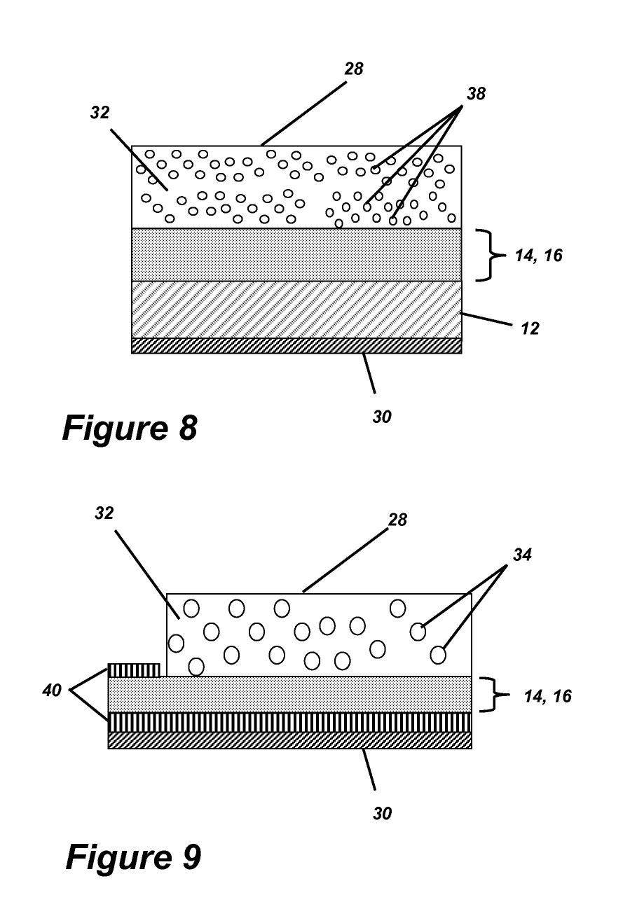

The idea of the present invention may be expanded by incorporating some optically active (i.e. light emitting) material 38 into the overstructure 28 itself, as illustrated in FIG. 8, resulting a second active region that is optically pumped by the emitted light originating in the ensemble. This second active region, optically-pumped by the light originating in the current-injected quantum well layer 16, will re-emit at different wavelengths. This second active region can be obtained through incorporation of material 38 such as multiple quantum dots, multiple phosphors, dyes, light emitting polymers, or small molecules into the material 32 of the overstructure 28. Any type of color emission is achievable by suitable combination of well-chosen emitters at desired wavelengths.

Some light in the LED 10 is emitted towards the substrate 12, either within the escape angle and into the air, or into guided modes 22 in the substrate 10. As noted above, the bottom mirror 30, usually metallic, with high reflectivity, is added to reflect the downward energy flux. Results indicate a factor two increase in extracted light by using the mirror 30. Moreover, reflecting light emitted inside the substrate 12 towards the overstructure 28 ensures the light interacts with the light extracting features of the overstructure 28 and will be extracted. In this manner, all light initially emitted from the (Al, Ga, In)N layer 14 and active layer 16 will be extracted.

It can be advantageous to avoid the substrate 12 altogether by using any substrate 12 removal technique, such as laser lift-off. After the substrate 12 has been removed, a good bottom mirror 30 may then be placed or incorporated on an exposed surface of the ensemble, i.e., an exposed surface of the (Al, Ga, In)N layer 14, wherein the bottom mirror 30 also acts as an electrical contact and thermal sink, thereby improving both electrical and thermal properties at once.

In order to diminish metallic contact loss, transparent contacts 40 may be used, as illustrated in FIG. 9. Typically, one or more transparent contacts 40 are deposited on a surface of the device 10.

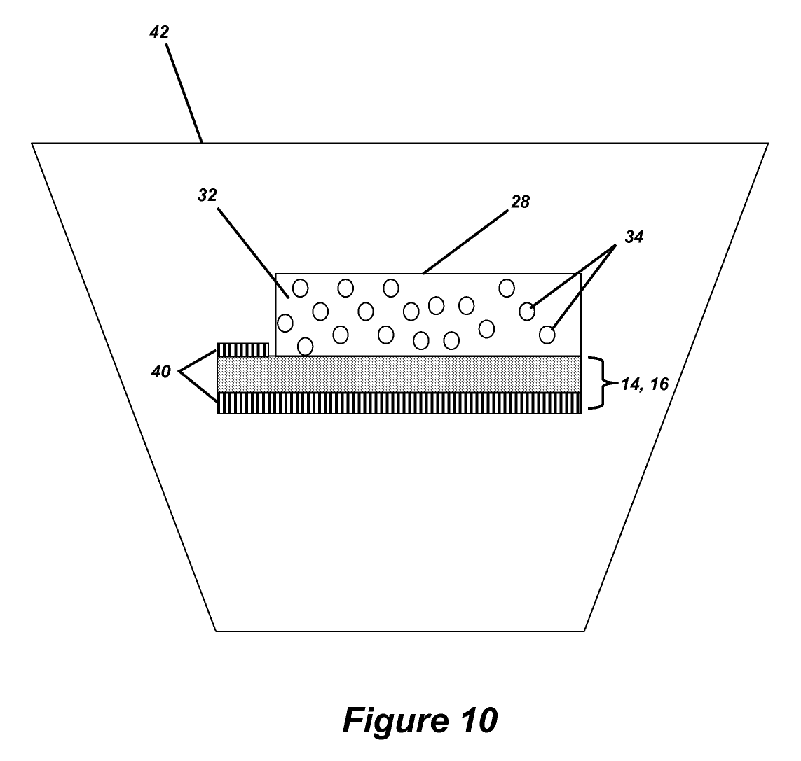

In addition, it may be useful to incorporate or position the entire device 10 within a high index of refraction materials, such as a beam expander/extractor 42, as illustrated in FIG. 10, to extract the emitted light, in order to minimize interactions between reflected beams inside the structure and metallic contacts, which are always a source of loss.

In summary, the present invention describes an optoelectronic device 10, comprised of one or more III-nitride active layers 14, 16 for emitting light, and an overstructure 28, formed over the III-nitride active layers 14, 16, that suppresses light trapped within the III-nitride active layers 14, 16 by using, as an escape facilitator, a material 32 with an index of refraction at least matching an index of refraction of the III-nitride active layers 14, 16, in order to extract the emitted light from the device 10.

Of course, the present invention's concepts can be extended to LEDs based on other semiconductor materials, such as ZnO, for example. The present invention may even be extended to other light emitting materials such as organic materials, light emitting polymers, light emitting small molecules, and so forth.

### REFERENCES

The following references are incorporated by reference herein:
[1] U.S. Pat. No. 6,538,371, issued Mar. 25, 2003, to Duggal et al. and entitled “White Light Illumination System.”
[2] U.S. Pat. No. 6,525,464, issued Feb. 25, 2003, to Y-C. Chin, entitled “Stacked Light-Mixing LED.”
[3] U.S. Pat. No. 6,504,180, issued Jan. 7, 2003, Heremans et al., and entitled “Method of Manufacturing Surface Textured High Efficiency Radiating Devices And Devices Obtained Therefrom.”
[4] U.S. Pat. No. 6,163,038, issued Dec. 19, 2000 to Chen et al. and entitled “White Light Emitting Diode and Method of Manufacturing the Same.”
[5] U.S. Pat. No. 5,779,924, issued Jul. 14, 1998, to Krames et al. and entitled “Ordered Interface Texturing For a Light Emitting Device.”
[6] U.S. Pat. No. 5,362,977, issued Nov. 8, 1994, to Hunt et al. and entitled “Single Mirror Light Emitting Diodes with Enhanced Intensity.”
[7] U.S. Pat. No. 5,226,053, issued Jul. 6, 1993, to Cho et al., and entitled “Light Emitting Diode.”
[10] X. Guo, J. W. Graff and E. F. Schubert, “Photon Recycling Semiconductor Light Emitting diode,” IEDM Technical Digest, IEDM-99, p. 600 (1999)
[11] M. R. Krames et al. “High-power truncated-inverted-pyramid (AlₓGa₁₋ₓ)_{0.5}In_{0.5}P/GaP light-emitting diodes exhibiting greater than 50% external quantum efficiency,” Applied physics letters, vol. 75, pp. 2365-2367, (1999).
[12] W. Schmid, R. Jager, F. Eberhard, R. King, M. Miller, J. Joos, and K. J. Ebeling, “45% Quantum Efficiency Light-Emitting-Diodes with Radial Outcoupling Taper,” presented at SPIE, San Jose, 3938, pp. 90-97 California, (2000).
[13] T. Fujii et al., “Cone-shaped surface GaN-based light-emitting diodes,” Physica Status Solidi C, no. 7, pp. 2836-40 (2005).
[14] Z. H. Feng and K. M. Lau, “Enhanced luminescence from GaN-based blue LEDs grown on grooved sapphire substrates,” IEEE Photonics Technology Letters, vol. 17, no. 9, pp. 1812-14 (September 2005).
[15] T. Gessmann et al., “Light-emitting diodes with integrated omnidirectionally reflective contacts,” Proceedings of the SPIE, vol. 5366, no. 1, pp. 53-61 (2004).
[16] R. Windisch et al., “InGaAlP thin film LEDs with high luminous efficiency,” Proceedings of the SPIE, vol. 5366, no. 1, pp. 43-52 (2004).
[17] Shnitzer, et al “30% External Quantum Efficiency From Surface Textured, Thin Film Light Emitting Diode,” Applied Physics Letters 63, page 2174-2176 (1993).
[18] M. Boroditsky and E. Yablonovitch, “Light extraction efficiency from light-emitting diodes,” Proceedings of the SPIE—The International Society for Optical Engineering, SPIE-Int. Soc. Opt. Eng, 3002. p. 119-122, (1997).
[19] H. Benisty, H. D. Neve, and C. Weisbuch “Impact of planar microcavity effects on light extraction: basic concepts and analytical trends,” IEEE J. Quantum Electron vol. 34 p. 1612 (1998).
[20] D. Delbeke, R. Bockstaele, P. Bienstman, R. Baets, and H. Benisty, “High-efficiency Semiconductor Resonant-Cavity Light-Emitting diodes: A review,” IEEE Journal on selected topic in Quantum Electron vol. 8, no. 2 p. 189, (2002).
[21] A. David et al., “Photonic crystal laser lift-off GaN light-emitting diodes,” Applied Physics Letters, vol. 88, pp. 133514-1-3 (2006).

### CONCLUSION

This concludes the description of the preferred embodiment of the present invention. The foregoing description of one or more embodiments of the invention has been presented for the purposes of illustration and description. It is not intended to be exhaustive or to limit the invention to the precise form disclosed. Many modifications and variations are possible in light of the above teaching. It is intended that the scope of the invention be limited not by this detailed description, but rather by the claims appended hereto.

What is claimed is:

1. An optoelectronic device, comprising:
(a) a substrate;
(b) an ensemble comprised of insulating and semiconducting materials formed on the substrate and including one or more III-nitride active layers for emitting light; and
(c) an overstructure, formed over the ensemble, for suppressing guided modes within the ensemble by having an index of refraction at least matching an index of refraction of the ensemble, wherein the overstructure acts as a light extractor for the emitted light.

2. The device of claim 1, wherein the overstructure has an index of refraction higher than the index of refraction of the ensemble.

3. The device of claim 1, wherein the overstructure is comprised of high and low index of refraction materials.

4. The device of claim 1, wherein the overstructure includes inhomogeneities for scattering the emitted light out of the overstructure.

5. The device of claim 4, wherein the inhomogeneities are achieved by shaping the overstructure, by incorporating materials having a variable index of refraction into the overstructure, by incorporating holes into the overstructure, or by structuring a surface of the overstructure.

6. The device of claim 1, wherein the overstructure incorporates optically active material, resulting a second active region that is optically pumped by the emitted light originating in the ensemble.

7. The device of claim 1, wherein a top surface of the overstructure is roughened, textured, patterned, or formed into a shape to enhance extraction of the emitted light.

8. The device of claim 1, further comprising a mirror positioned in proximity to the ensemble for reflecting the emitted light within the device towards the overstructure, so that the emitted light interacts with light extracting features of the overstructure.

9. The device of claim 8, wherein the mirror is formed on a surface of the substrate.

10. The device of claim 8, wherein the substrate has been removed and the mirror is placed on an exposed surface of the ensemble.

11. The device of claim 1, wherein the optoelectronic device is positioned within a high index of refraction material to extract the emitted light.

12. The device of claim 1, further comprising one or more transparent contacts deposited on a surface of the device.

13. An optoelectronic device, comprising:
(a) one or more III-nitride active layers for emitting light; and
(b) an overstructure, formed over the layers, that suppresses light trapped within the III-nitride active layers by using, as an escape facilitator, a material with an index of refraction at least matching an index of refraction of the III-nitride active layers, in order to extract the emitted light from the device.

14. A method of fabricating an optoelectronic device, comprising:
(a) providing a substrate;
(b) forming an ensemble comprised of insulating and semiconducting materials on the substrate and including one or more III-nitride active layers for emitting light; and
(c) forming an overstructure, over the ensemble, for suppressing guided modes within the ensemble by having an index of refraction at least matching an index of refraction of the ensemble, wherein the overstructure acts as a light extractor for the emitted light.

15. A method of fabricating an optoelectronic device, comprising:
(a) creating one or more III-nitride active layers for emitting light; and
(b) creating an overstructure, over the III-nitride active layers, that suppresses light trapped within the III-nitride active layers by using, as an escape facilitator, a material with an index of refraction at least matching an index of refraction of the III-nitride active layers, in order to extract the emitted light from the device.
